(19) United States
(12) Patent Application Publication
(10) Pub. No.: US 2009/0298267 A1
(43) Pub. Date: Dec. 3, 2009

(54) SEMICONDUCTOR DEVICE MANUFACTURING APPARATUS AND SEMICONDUCTOR DEVICE MANUFACTURING METHOD

(75) Inventor: Yukihiro Hashimoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/539,017

(22) Filed: Aug. 11, 2009

Related U.S. Application Data
(63) Continuation of application No. PCT/JP2007/055427, filed on Mar. 16, 2007.

(51) Int. Cl. H01L 21/20; C23C 16/54

(52) U.S. Cl. 438/478; 118/720; 257/E21.09

(57) ABSTRACT

It is an apparatus for semiconductor device production in which a feed gas is fed into a chamber having a semiconductor wafer placed therein to deposit a thin film on the surface of the semiconductor wafer based on a catalyzed chemical reaction. It comprises the chamber for placing a semiconductor wafer therein, a feed gas supply means with which a feed gas which is a raw material for the thin film is sent into the chamber, and a gas-blowing means which has a gas-blowing opening through which the feed gas sent from the feed gas supply means is blown against the surface of the semiconductor wafer placed in the chamber. The gas-blowing means changes in the state of the gas-blowing opening according to the feed gas blowing position to thereby regulate the amount of the feed gas to be blown.

### CROSS-REFERENCE TO RELATED APPLICATIONS

This is a continuation of Application PCT/JP2007/055427, filed on Mar. 16, 2007, now pending, the contents of which are herein wholly incorporated by reference.

### FIELD

The embodiments discussed herein are relates to a semiconductor device manufacturing apparatus and a semiconductor device manufacturing method.

### BACKGROUND

The semiconductor device is manufactured by growing various kinds of films (e.g. silicon films) on the surface of a semiconductor wafer and applying a photo resist. A CVD (Chemical Vapor Deposition) method making use of chemical catalyst reaction is exemplified as a method of growing the silicon film on the surface of the semiconductor wafer.

For example, Patent document 1 describes a technology of forming a vapor deposition film having a uniform film thickness in a way that equalizes a film growth velocity over an entire internal surface of a hollowed container in which to grow the thin film by providing discharge ports for discharging a raw gas in an axial direction and in a radial direction. Further, Patent document 2 describes a technology of broadening a plasma lead-out window when growing the film but narrowing the plasma lead-out window on the occasion of etching in order to uniformize the thickness of the film to be formed or an etching depth. Furthermore, Patent document 3 describes a technology of growing the thin films on a plurality of semiconductor wafers by a plasma CVD method and restraining a scatter in film thickness on the plurality of semiconductor wafers by adjusting a flow rate of a reactive gas flowing to the semiconductor wafer at each electrode portion. Still further, Patent document 4 describes a technology of providing a multiplicity of reactive gas blowout ports disposed in a face-to-face relationship with the semiconductor wafer and arranged in radial lines from the center of the electrode, and ensuring the uniformity of a distribution of the film thickness by blocking off unnecessary holes with screws when adjusting the distribution of the film thickness.

The chamber type single wafer CVD apparatus and the plasma CVD apparatus restrain the scatter in the distribution of the film thickness after growing the film down to approximately 2% or under by uniformizing the gas blasting quantity against the wafer in a way that controls the blowout of the gas as described above.

| | | |
|---|---|---|
| [Patent document 1] Japanese | Patent | Laid-Open |
| Publication No. 2005-89798 | | |
| [Patent document 2] Japanese | Patent | Publication |
| No. 2913657 | | |
| [Patent document 3] Japanese | Patent | Laid-Open |
| Publication No. H01-295414 | | |
| [Patent document 4] Japanese | Patent | Laid-Open |
| Publication No. S59-38374 | | |

### SUMMARY

A semiconductor device manufacturing apparatus which supplies a raw gas into a chamber accommodating a semiconductor wafer and deposits a thin film on the surface of the semiconductor wafer by making use of chemical catalyst reaction, include: a chamber accommodating the semiconductor wafer; raw gas supplying unit to supply the raw gas as a raw material of the thin film into the chamber; and gas blowout unit, includes a gas blowout port via which the raw gas supplied from the raw gas supplying unit is blasted against the surface of the semiconductor wafer accommodated within the chamber, to adjust a blasting quality of the raw gas by changing a state of the gas blowout port corresponding to a blasting position of the raw gas.

Further, the embodiments discussed herein is grasped from an aspect of a manufacturing method. Namely, according to the embodiments discussed herein, a semiconductor device manufacturing method which supplies a raw gas into a chamber accommodating a semiconductor wafer and deposits a thin film on the surface of said semiconductor wafer by making use of chemical catalyst reaction, may comprise adjusting a blasting quality of the raw gas of adjusting a blasting quality of the raw gas by changing a state of a gas blowout port corresponding to a blasting position of the raw gas.

The object and advantage of the embodiment will be realized and attained by means of the elements and combinations particularly pointed out in the claims.

It is to be understood that both the foregoing general description and the following detailed description are exemplary and explanatory only and are not restrictive of the invention, as claimed.

### BRIEF DESCRIPTION OF THE DRAWINGS

FIG. 1 is a view of a configuration of a semiconductor device manufacturing apparatus;

FIG. 2A is a top view of gas flow rate variable plates;

FIG. 2B is a top view of the gas flow rate variable plates;

FIG. 3A is a top view of the gas flow rate variable plates in a state of being superposed on each other;

FIG. 3B is a top view of the gas flow rate variable plates in the state of being superposed on each other;

FIG. 3C is a top view of the gas flow rate variable plates in the state of being superposed on each other;

FIG. 4A is a top view of the gas flow rate variable plates;

FIG. 4B is a top view of the gas flow rate variable plates;

FIG. 4C is a top view of the gas flow rate variable plates;

FIG. 4D is a top view of the gas flow rate variable plates;

FIG. 4E is a top view of the gas flow rate variable plates;

FIG. 4F is a top view of the gas flow rate variable plates;

FIG. 4G is a top view of the gas flow rate variable plates;

FIG. 5 is a diagram of one example of a map;

FIG. 6 is a flowchart of a processing flow of the semiconductor device manufacturing apparatus;

FIG. 7 is a view illustrating one example of measuring points when measuring a film thickness; and

FIG. 8 is a view depicting a flow of a raw gas flows and a change of deposition of a thin film when the film is grown.

### DESCRIPTION OF EMBODIMENTS

A semiconductor device manufacturing apparatus and a semiconductor device manufacturing method according to an exemplary embodiment of the embodiments discussed herein will hereinafter be described with reference to the drawings. The embodiment is an exemplification, and the embodiments discussed herein are not limited to the configuration in the embodiment.

### <Configuration>

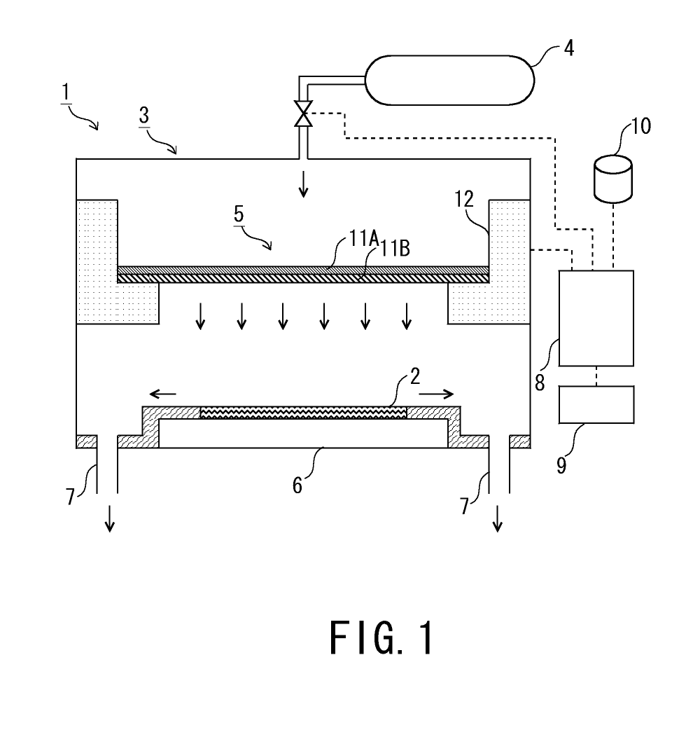

FIG. 1 depicts a configuration of a semiconductor device manufacturing apparatus (which will hereinafter be called a manufacturing apparatus 1) according to one embodiment of the embodiments discussed herein. As illustrated in FIG. 1, the manufacturing apparatus 1 is equipped with a (main) chamber 3 accommodating a semiconductor wafer 2, a gas supplying unit 4 which supplies a raw gas into the chamber, a gas blowout unit 5 which adjusts a blasting quantity of the raw gas against the surface of the semiconductor wafer 2, a wafer support table 6 on which to place the semiconductor wafer 2, a discharge port 7 for discharging the raw gas from within the chamber, and a controller 8 which controls the gas blowout unit 5 and the gas supplying unit 4. An input unit 9 and a storage unit 10 stored with a map are connected to the controller 8.

The chamber 3 has a size that is large enough to accommodate the semiconductor wafer 2. The wafer support table 6 for placing the semiconductor wafer 2 on a floor surface is disposed in a reaction chamber of the main chamber 3, and further the gas blowout unit 5 is disposed upwardly of the wafer support table 6. Hence, it follows that the raw gas supplied from the gas supplying unit 4 is blown out against the wafer support table 6 from the gas blowout unit 5. Incidentally, such a contrivance is given that the discharge port 7 for discharging the raw gas is formed in the floor surface peripheral to the wafer support table 6, whereby the unnecessary raw gas is discharged from the reaction chamber.

The gas supplying unit 4 supplies the reaction chamber of the main chamber 3 with the gas serving as a raw material of a thin film, which is deposited on the surface of the semiconductor wafer 2. The raw gas is composed of, e.g., a SiH₄+O₂ gas, etc. The gas supplying unit 4 controls a valve to open and close according to an instruction given from the controller 8, thus supplying and stopping the raw gas. Note that the gas supplying unit 4 may change a flow rate of the raw gas to be supplied in a way that uses a flow rate adjusting valve.

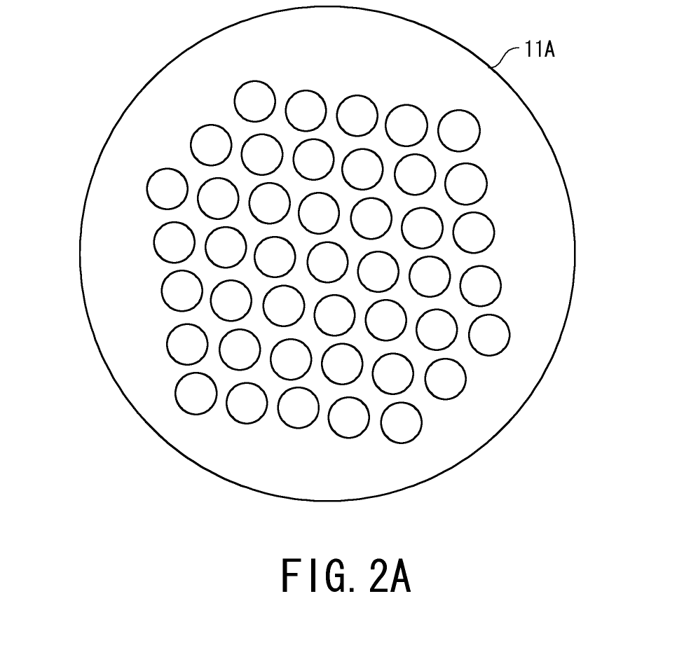

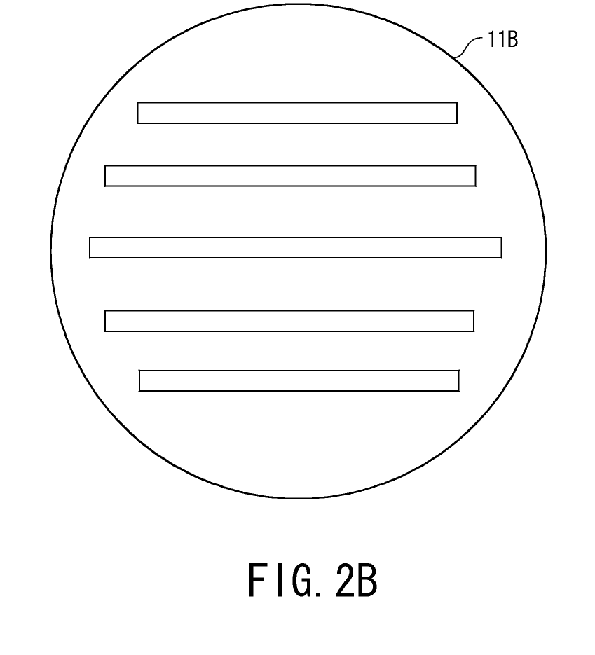

The gas blowout unit 5 is constructed of gas flow rate variable plates 11A, 11B and a drive unit 12. FIG. 2A illustrates a top view of the gas flow rate variable plate 11A, and FIG. 2B illustrates a top view of the gas flow rate variable plate 11B, respectively. As depicted in FIGS. 2A and 2B, the gas flowrate variable plates 11A, 11B are provided with holes and slits taking a variety of shapes. To be specific, for example, the plates 11A, 11B are provided with a plurality of circular holes having different shapes and different dimensions and with rectangular slits having different lengths and different breadths. Note that the breadth of the slit may also be increased, e.g., on a slit-by-slit basis.

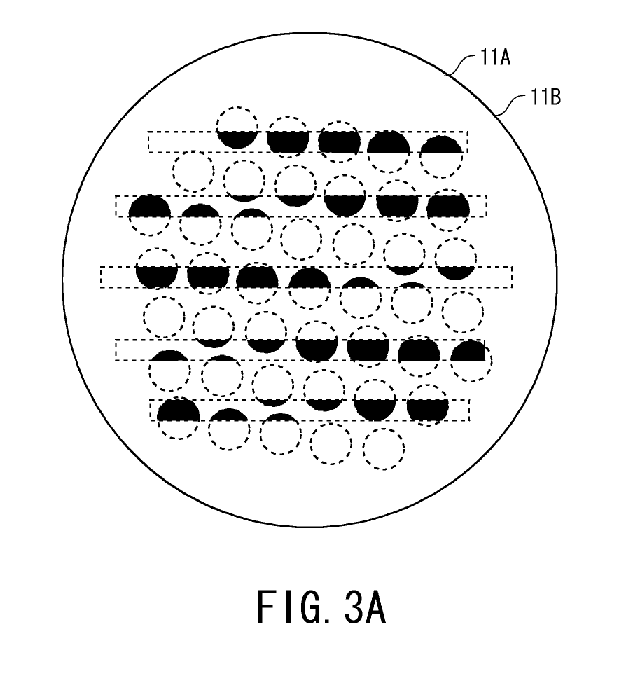

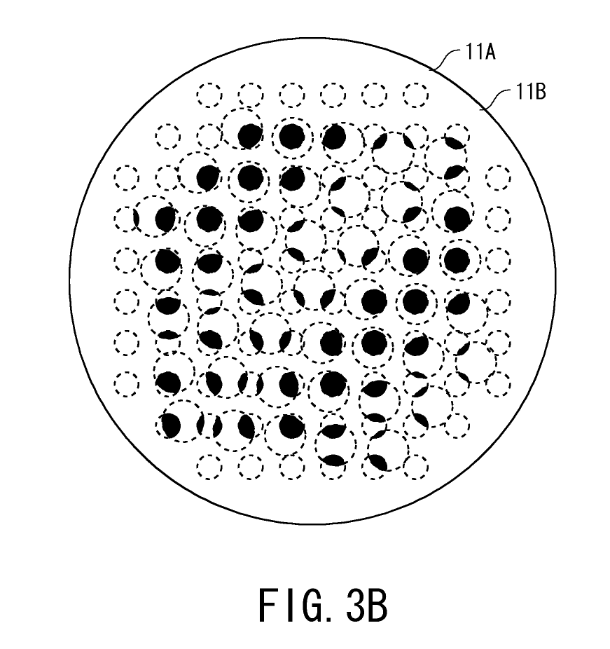

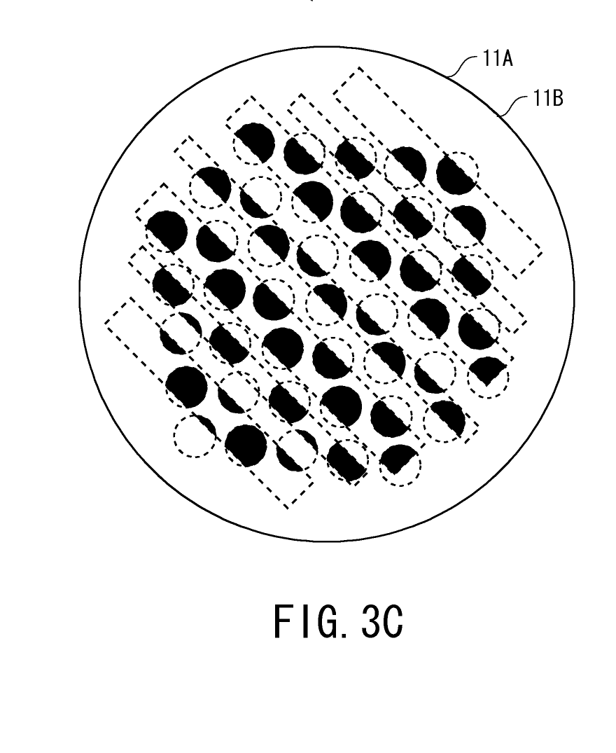

FIGS. 3A-3C illustrate top views of the gas flow rate variable plates 11A, 11B in an overlapped state. Portions depicted in solid black in FIGS. 3A-3C represent the holes via which the gas flows. As illustrated in FIGS. 3A-3C, the gas flow rate variable plates 11A, 11B formed with the multiplicity of holes are superposed on each other and rotated by the drive unit 12, thereby changing the shapes of the holes through which the raw gas passes. This contrivance enables the gas to be blown out at a desired flow rate corresponding to the blowout position of the semiconductor wafer 2. To be specific, the two sheets of plates formed with the multiplicity of holes are superposed on each other, and one or both of the plates are rotated so as to change the relative positional relationship between the two plates. Areas of apertures through which the raw gas passes are controlled by changing the relative positional relationship between the two plates. For example, the two plates formed with fan-shaped holes each having 90 degrees in central angle are superposed on each other, and the relative positional relationship is changed, whereby the shape of the hole through which the raw gas passes can be controlled within a range of 0-90 degrees.

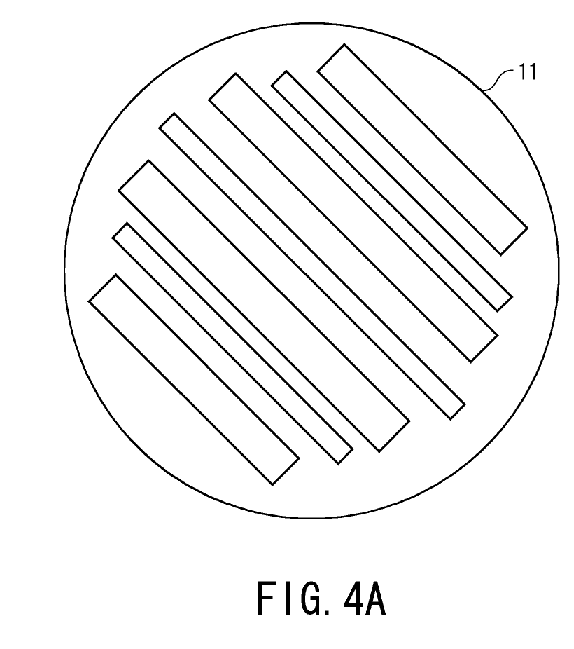

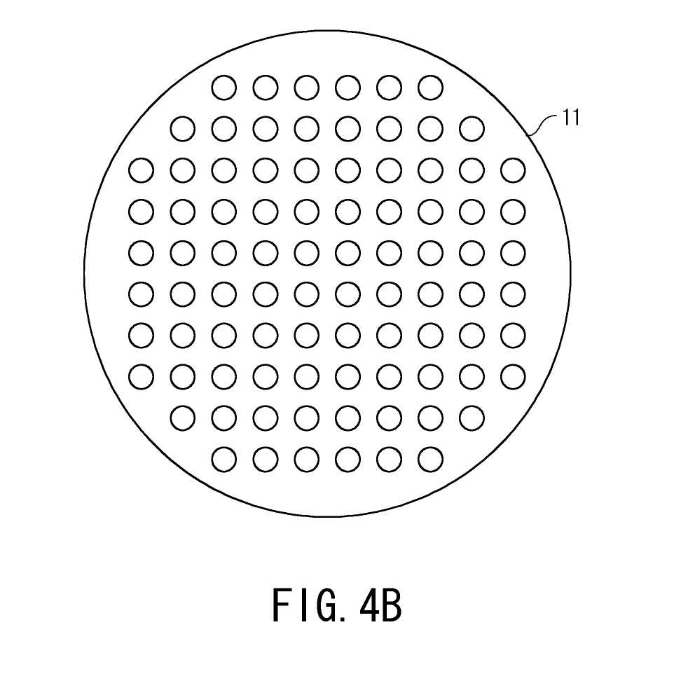

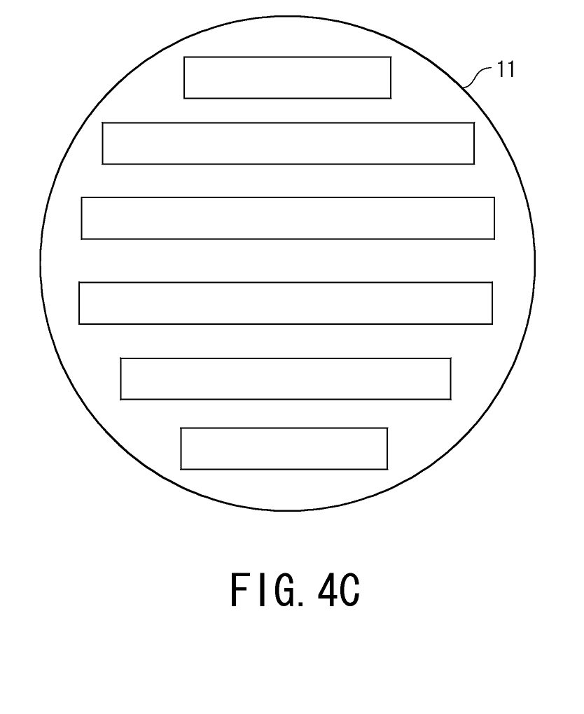

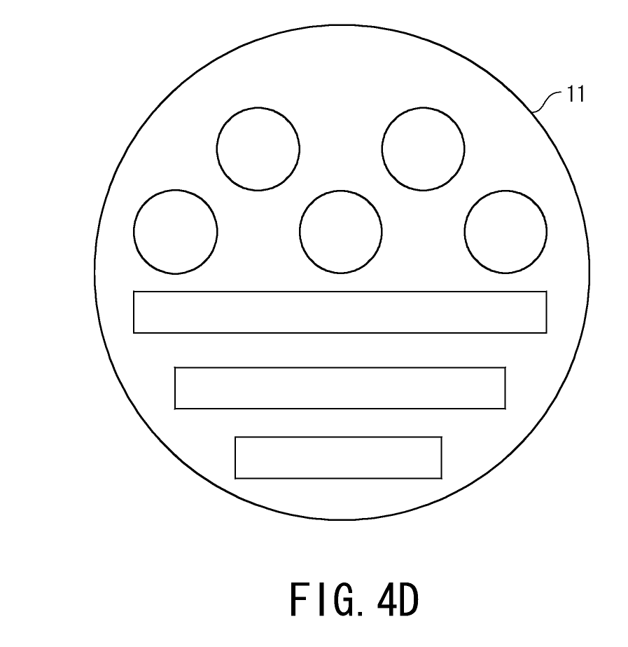

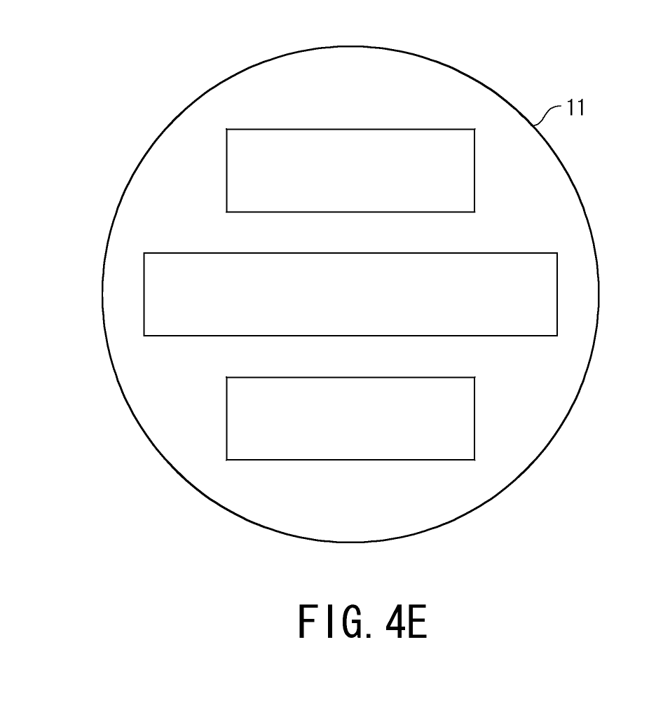

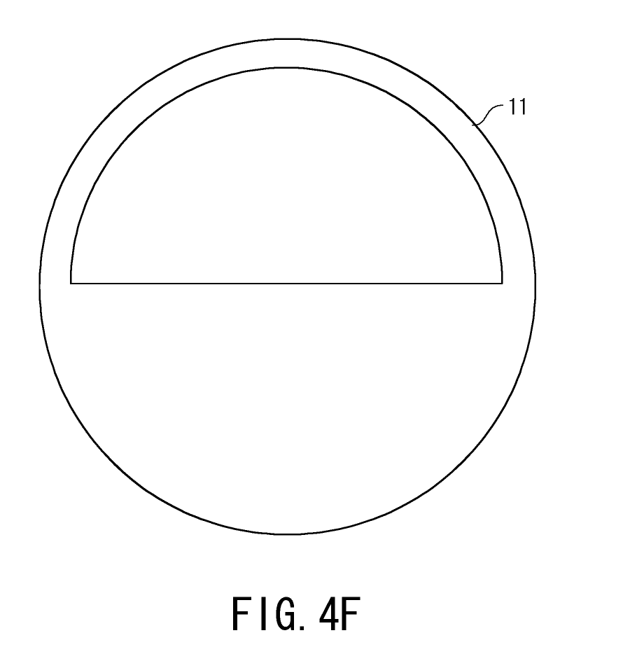

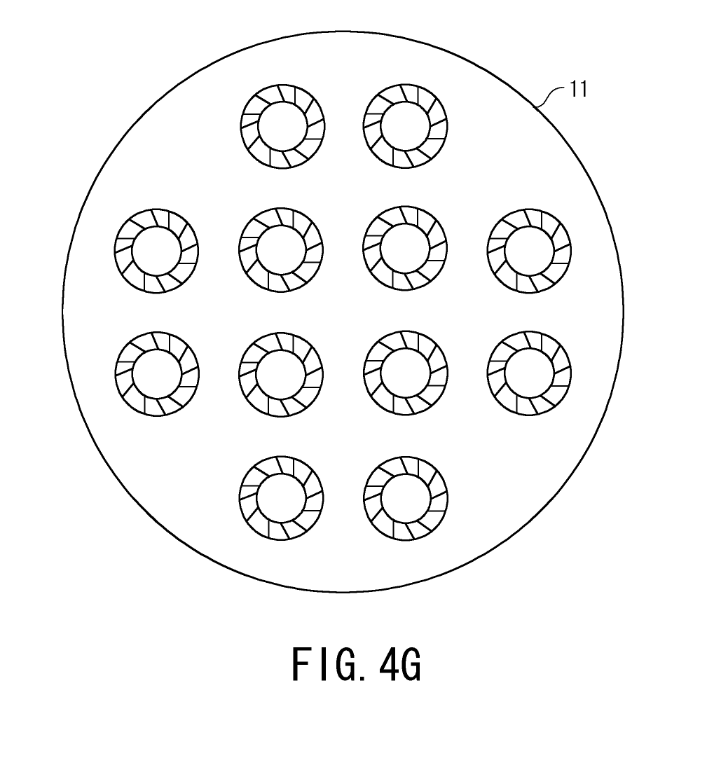

Note that the gas flow rate variable plates 11A, 11B are not limited to those depicted in FIGS. 2A, 2B but may take configurations formed with the holes taking shapes as illustrated in FIGS. 4A-4F. Specifically, the available plates have a configuration in which the slit with a small breadth and the slit with a large breadth are arranged alternately (FIG. 4A), a configuration in which the holes having the same size are arrayed in matrix (FIG. 4B), a configuration in which the slits each having the same breadth are arranged (FIG. 4C), a configuration in which the rectangular slits and the circular holes are disposed in mixture, a configuration in which the large slits are provided in the vicinity of the central area (FIG. 4E), and a configuration in which a fan-shaped hole having 180 degrees in central angle is formed (FIG. 4F). Moreover, in the embodiment, the two gas flow rate variable plates 11 are superposed on each other, however, the embodiments discussed herein is not limited to this number of plates, and three or more plates may be superposed, in which a desired distribution of the blowout flow rate of the raw gas blown out against the semiconductor wafer 2 is attained by properly combining the gas flow rate variable plates 11 formed with the holes taking the variety of shapes.

Moreover, in the embodiment, the desired distribution of the blowout flow rate of the raw gas is attained by the gas flow rate variable plates 11 formed with the holes in the variety of shapes, however, the embodiments discussed herein is not limited to this scheme. Namely, as illustrated in FIG. 4G, another available scheme is that a plurality of pinnae is disposed in the hole from which the raw gas is blown out, and a size of a flow path of the raw gas is changed by moving the pinnae in an iris-like shape (which is, i.e., an iris structure used for a diaphragm of an optical apparatus such as a camera), thus obtaining the desired distribution of the blowout flow rate of the raw gas blown out against the semiconductor wafer 2.

The controller 8 controls the gas blowout unit 5 and the gas supplying unit 4 in response to a command given from an operator, which is inputted to the input unit 9. The controller 8 refers to the map stored in the storage unit 10 and controls, based on this map, the gas blowout unit 5, thereby adjusting the blowout flow rate of the raw gas blown out against the semiconductor wafer 2 to become the desired flow-rate distribution.

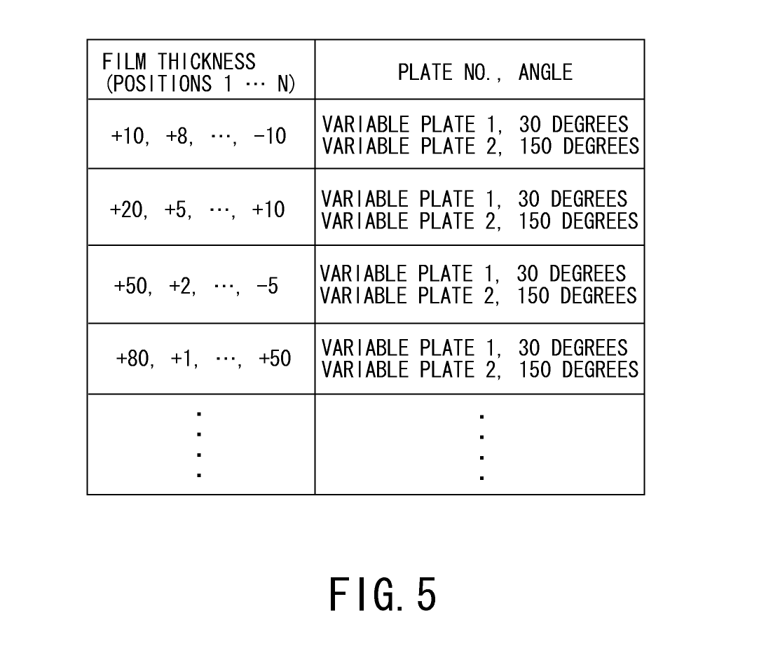

The map stored in the storage unit 10 manifests a relationship between positions of the gas flow rate variable plates 11A, 11B and a thickness of the thin film grown on the semiconductor wafer 2. FIG. 5 illustrates one example of the map. The controller 8 acquires position data of the gas flow rate variable plates 11A, 11B, which match with a thickness distribution, requested by the operator, of the thin film, and controls the gas blowout unit 5 so that the gas flow rate variable plates 11A, 11B match with the acquired distribution.

### <Processing Flow>

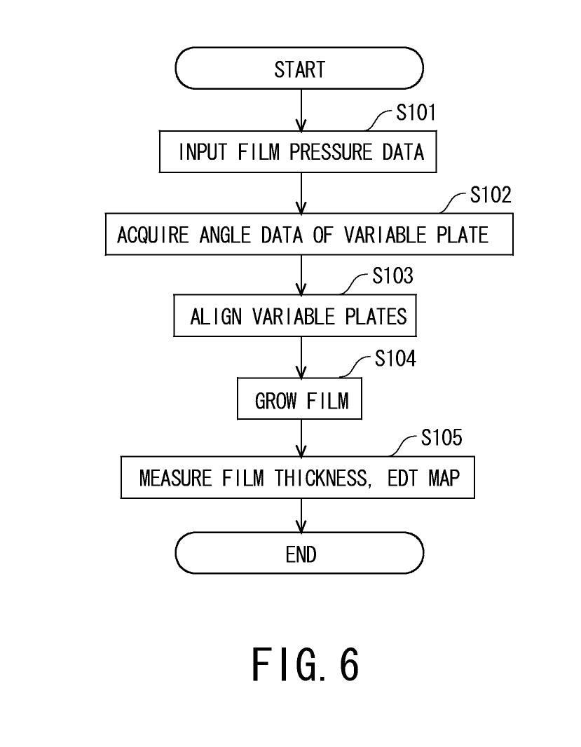

Next, a processing flow of the manufacturing apparatus 1 will hereinafter be described. FIG. 6 is a flowchart of the processing flow of the manufacturing apparatus 1.

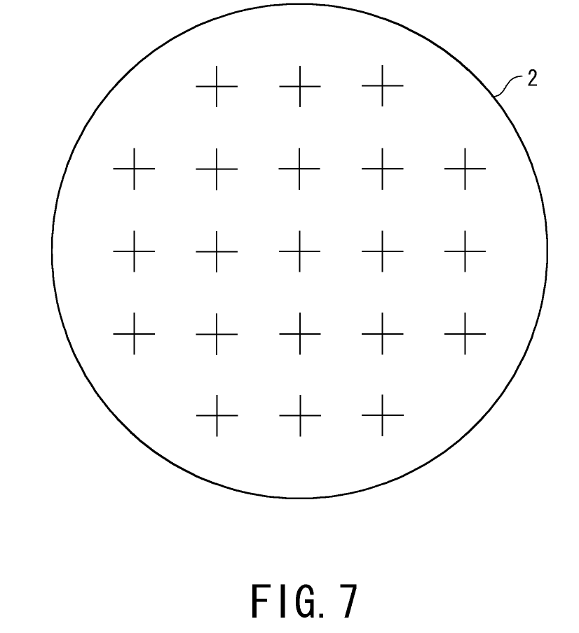

(Step S101) To begin with, the operator inputs the thickness data of the thin film to be grown to the input unit 9. The data inputted by the operator represent the thicknesses of the thin film at, e.g., as depicted in FIG. 7, a multiplicity of measuring points set on the semiconductor wafer 2.

(Step S102) The controller 8 refers to the map in the storage unit 10 and thus acquires the position data of the gas flow rate variable plates 11A, 11B, which match with the thickness data of the thin film that are inputted by the operator.

(Step S103) The controller 8 rotates the gas flow rate variable plates 11A, 11B respectively in a way that matches with the acquired position data of the gas flow rate variable plates 11A, 11B.

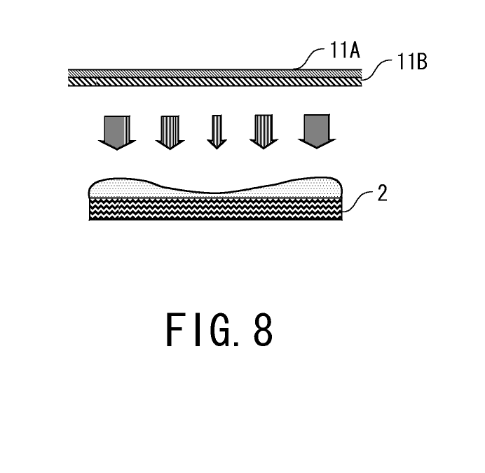

(Step S104) The controller 8, when the gas flow rate variable plates 11A, 11B reach the desired positions, supplies the raw gas into the chamber 3 by opening a valve, and starts growing the thin film. FIG. 8 illustrates how the raw gas flows and how much the thin film is deposited when growing the film. As depicted in FIG. 8, the gas flow rate variable plates 11A, 11B change the distribution of the blowout flow rate of the raw gas, corresponding to the position of the semiconductor wafer 2, and hence the thickness of the thin deposited can be changed corresponding to the position of the semiconductor wafer 2.

(Step S105) The controller 8, after a fixed period of time has elapsed, finishes growing the thin film by closing the valve. Note that the operator measures the thickness of the thin film of the semiconductor wafer 2 after the film has been grown and may, if the thickness of the thin film is not coincident with the desired film thickness, again grows the thin film so that the thin film comes to have the desired film thickness by arbitrarily changing the positions of the gas flow rate variable plates 11A, 11B. A further available scheme is that the thickness data of the thus-grown thin film are reflected in the map, and this map may be reflected in when growing the film from next time.

With this processes described above, the manufacturing apparatus 1 enables the thin film to be grown so as to acquire the desired distribution of the film thickness. Namely, with this contrivance, it is feasible to grow the thin film having the distribution of the film thickness corresponding to an etching characteristic distribution and a CMP (Chemical Mechanical Polishing) flatness characteristic distribution of the apparatuses employed for an etching process and a CMP process of the semiconductor wafer 2, which are to be carried out thereafter. It is therefore possible to reduce a difference in performance between the apparatuses each processing the semiconductor wafer and to expand a margin for a dimensional error etc on the occasion of mass-production. Further, mass-production capability can be improved by taking the matching property of the manufacturing apparatus between the processes. Moreover, even if a scatter occurs in the distribution of the film thickness due to influence of metal wiring etc formed as a base, it is feasible to grow the thin film having the distribution of the film thickness, which takes these external factors into consideration.

The prior art entails controlling the flow rate in a state of establishing a one-to-one relationship between the gas blowout port and the gas flow rate controller (e.g., a mass flow controller) and therefore has such a problem that the manufacturing apparatus increases in size, however, according to the invention of the present application, the thin film with the desired distribution of the film thickness can be grown without increasing the size of the apparatus.

Over the recent years, there has been increasingly a request for micronization of a semiconductor element, and it has been difficult to meet this request simply by ameliorating performance of each process. For example, if restraining the scatter in the distribution of the film thickness on the surface of the semiconductor wafer in the CVD process, a matching property between an etching distribution based on an etching process and a polishing quantity based on a CMP process, which are executed after the CVD process, resulting in such a case that global waviness (steps) are formed on the surface of the semiconductor wafer. Consequently, inconvenience occurs in a photo process, and it follows that a large load is imposed on management for patterning.

Tolerances of process conditions in the whole processes are narrowed due to the improvement of the performance of the single process, which resultantly causes unstable characteristics of the semiconductor device, and there are an increased number of cases of leading to a decrease in yield, a rise in defective products and a decline of reliability.

Such being the case, the embodiments discussed herein aims at providing a semiconductor device manufacturing apparatus and a semiconductor device manufacturing method, which adjust a blasting quantity of a raw gas corresponding to a blasting position of the raw gas.

According to the embodiments discussed herein, a solution of the problems described above involves changing the blasting quantity of the raw gas corresponding to the blasting position of the raw gas on the occasion of growing the thin film on the semiconductor wafer.

It is feasible to provide the semiconductor device manufacturing apparatus and the semiconductor device manufacturing method, which adjust the blasting quantity of the raw gas corresponding to the blasting position of the raw gas.

All example and conditional language recited herein are intended for pedagogical purposes to aid the reader in understanding the invention and the concepts contributed by the inventor to furthering the art, and are to be construed as being without limitation to such specifically recited examples and conditions, nor does the organization of such example in the specification relate to a showing of the superiority and inferiority of the invention. Although the embodiment(s) of the present invention(s) has (have) been described in detail, it should be understood that the various changes, substitutions, and alterations could be made hereto without departing from the spirit and scope of the invention.

What is claimed is:

1. A semiconductor device manufacturing apparatus which supplies a raw gas into a chamber accommodating a semiconductor wafer and deposits a thin film on the surface of said semiconductor wafer by making use of chemical catalyst reaction, comprising:
a chamber accommodating said semiconductor wafer;
raw gas supplying unit to supply the raw gas as a raw material of said thin film into said chamber; and
gas blowout unit, includes a gas blowout port via which the raw gas supplied from said raw gas supplying unit is blasted against the surface of said semiconductor wafer accommodated within said chamber, to adjust a blasting quality of the raw gas by changing a state of the gas blowout port corresponding to a blasting position of the raw gas.

2. The semiconductor device manufacturing apparatus according to claim 1, wherein said gas blowout unit changes the blasting quantity of the raw gas blasted against the surface of said semiconductor wafer in a way that changes a size of the gas blowout port corresponding to the blasting position of the raw gas.

3. The semiconductor device manufacturing apparatus according to claim 1, wherein said gas blowout unit includes a plurality of gas blowout ports.

4. The semiconductor device manufacturing apparatus according to claim 1, wherein said gas blowout unit changes the blasting quantity of the raw gas blasted against the surface of said semiconductor wafer in a way that changes the number of the gas blowout ports corresponding to the blasting position of the raw gas.

5. The semiconductor device manufacturing apparatus according to claim 1, wherein said gas blowout unit includes a plate group having a first plate in which the plurality of gas blowout ports is arranged and a second plate in which the plurality of gas blowout ports is arranged, which are superposed on each other, and changes the blasting quantity of the raw gas blasted against the surface of said semiconductor wafer in a way that changes a relative position between said first plate and said second plate.

6. The semiconductor device manufacturing apparatus according to claim 5, wherein said gas blowout unit further includes a rotating mechanism rotating at least any one of said first plate and said second plate, and changes the relative position between said first plate and said second plate by driving said rotating mechanism.

7. The semiconductor device manufacturing apparatus according to claim 5, wherein the plurality of gas blowout ports of said first plate and the plurality of gas blowout ports of said second port are formed so as to be different in shape or size from each other.

8. The semiconductor device manufacturing apparatus according to claim 1, wherein the gas blowout port changes the blasting quantity of the raw gas blasted against the surface of said semiconductor wafer by changing a size of a flow path of the raw gas in a way that moves a plurality of pinnae disposed within the gas blowout port in an iris-like shape.

9. The semiconductor device manufacturing apparatus according to claim 1, wherein said raw gas supplying unit changes the blasting quantity of the raw gas blasted against the surface of said semiconductor wafer by controlling at least one or more of a pressure, a flow rate and a flow velocity of the raw gas supplied into said chamber.

10. The semiconductor device manufacturing apparatus according to claim 1, wherein said gas blowout unit increases the blasting quantity of the raw gas in the case of augmenting a thickness of the thin film deposited on the surface of said semiconductor wafer but decreases the blasting quantity of the raw gas in the case of reducing the thickness of the thin film deposited on the surface of said semiconductor wafer.

11. The semiconductor device manufacturing apparatus according to claim 1, further comprising:
input unit to accept an input of film thickness data of the thin film that is to be grown on the surface of said semiconductor wafer; and
a map representing a relationship between data about a state of the gas blowout port and data about the film thickness of the thin film deposited on the surface of said semiconductor wafer,
wherein said gas blowout unit searches out, from said map, the data about the state of the gas blowout port, which is coincident with the film thickness data of the thin film that is inputted to said input unit, and changes the state of the gas blowout port so as to get coincident with the searched-out data about the state of the gas blowout port.

12. The semiconductor device manufacturing apparatus according to claim 1, wherein the thickness data of the thin film that is inputted to said input unit is determined corresponding to a content of a process executed on said semiconductor wafer on which the thin film is grown.

13. The semiconductor device manufacturing apparatus according to claim 1, wherein said gas blowout unit attains a desired thickness distribution of the thin film deposited on the surface of said semiconductor wafer by adjusting the blasting quantity of the raw gas.

14. A semiconductor device manufacturing method which supplies a raw gas into a chamber accommodating a semiconductor wafer and deposits a thin film on the surface of said semiconductor wafer by making use of chemical catalyst reaction, comprising:
adjusting a blasting quality of the raw gas by changing a state of a gas blowout port corresponding to a blasting position of the raw gas.

15. The semiconductor device manufacturing method according to claim 14, wherein said adjusting a blasting quality of the raw gas includes changing a blasting quantity of the raw gas blasted against the surface of said semiconductor wafer in a way that changes a size of the gas blowout port corresponding to a blasting position of the raw gas.

16. The semiconductor device manufacturing method according to claim 14, wherein said adjusting a blasting quality of the raw gas includes providing a plurality of gas blowout ports.

17. The semiconductor device manufacturing method according to claim 16, wherein said adjusting a blasting quality of the raw gas includes changing the blasting quantity of the raw gas blasted against the surface of said semiconductor wafer in a way that changes the number of the gas blowout ports corresponding to the blasting position of the raw gas.

18. The semiconductor device manufacturing method according to claim 14, wherein said adjusting a blasting quality of the raw gas includes providing a plate group having a first plate in which the plurality of gas blowout ports is arranged and a second plate in which the plurality of gas blowout ports is arranged, which are superposed on each other, and changing the blasting quantity of the raw gas blasted against the surface of said semiconductor wafer in a way that changes a relative position between said first plate and said second plate.

19. The semiconductor device manufacturing method according to claim 18, wherein said adjusting a blasting quality of the raw gas includes providing a rotating mechanism rotating at least any one of said first plate and said second plate, and changing the relative position between said first plate and said second plate by driving said rotating mechanism.

20. The semiconductor device manufacturing method according to claim 18, wherein the plurality of gas blowout ports of said first plate and the plurality of gas blowout ports of said second port are formed so as to be different in shape or size from each other.

21. The semiconductor device manufacturing method according to claim 14, wherein the gas blowout port changes the blasting quantity of the raw gas blasted against the surface of said semiconductor wafer by changing a size of a flow path of the raw gas in a way that moves a plurality of pinnae disposed within the gas blowout port in an iris-like shape.

22. The semiconductor device manufacturing method according to claim 14, wherein the blasting quantity of the raw gas blasted against the surface of said semiconductor wafer is changed by controlling at least one or more of a pressure, a flow rate and a flow velocity of the raw gas supplied into said chamber.

23. The semiconductor device manufacturing method according to claim 14, wherein said adjusting a blasting quality of the raw gas includes increasing the blasting quantity of the raw gas in the case of augmenting a thickness of the thin film deposited on the surface of said semiconductor wafer but decreases the blasting quantity of the raw gas in the case of reducing the thickness of the thin film deposited on the surface of said semiconductor wafer.

24. The semiconductor device manufacturing method according to claim 14, further comprising:
accepting an input of film thickness data of the thin film that is to be grown on the surface of said semiconductor wafer,
wherein said adjusting a blasting quality of the raw gas includes searching out, from a map representing a relationship between data about a state of the gas blowout port and data about the film thickness of the thin film deposited on the surface of said semiconductor wafer, the data about the state of the gas blowout port, which is coincident with the film thickness data of the thin film that is inputted in said accepting an input of film thickness data of the thin film, and changing the state of the gas blowout port so as to get coincident with the searched-out data about the state of the gas blowout port.

25. The semiconductor device manufacturing method according to claim 14, wherein the thickness data of the thin film that is inputted in said accepting an input of film thickness data of the thin film is determined corresponding to a content of a process executed on said semiconductor wafer on which the thin film is grown.

26. The semiconductor device manufacturing method according to claim 14, wherein said accepting an input of film thickness data of the thin film includes attaining a desired thickness distribution of the thin film deposited on the surface of said semiconductor wafer by adjusting the blasting quantity of the raw gas.
